(19) United States
(12) Patent Application Publication
(10) Pub. No.: US 2008/0169569 A1
(43) Pub. Date: Jul. 17, 2008

(54) Bonding pad of semiconductor integrated circuit, method for manufacturing the bonding pad, semiconductor integrated circuit, and electronic device

(75) Inventors: Kazuya Ishihara, Kurashiki-shi (JP); Nobuyoshi Awaya, Fukuyama-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka-shi (JP)

(21) Appl. No.: 12/003,718

(22) Filed: Dec. 31, 2007

(30) Foreign Application Priority Data
Jan. 16, 2007 (JP) 2007-007492

(51) Int. Cl. H01L 23/488

(52) U.S. Cl. 257/773; 257/E23.023

(57) ABSTRACT

According to the present invention, a bonding pad 10 of a semiconductor integrated circuit is arranged such that the opening pathways P through which metal wiring layers are connected have openings of at least two different widths including: a first width required to fill the opening pathway; and a second width being larger than the first width, and the openings are arranged lengthwise and crosswise.

This Nonprovisional application claims priority under 35 U.S.C. § 119(a) on patent application Ser. No. 7492/2007 filed in Japan on Jan. 16, 2007, the entire contents of which are hereby incorporated by reference.

### FIELD OF THE INVENTION

The present invention relates to (i) a bonding pad which is an external connection terminal of a wiring layer in a semiconductor integrated circuit and (ii) a method for manufacturing the bonding pad. Particularly, the present invention relates to (i) a bonding pad of a semiconductor integrated circuit which pad has multilayer metal wiring layer made up of two or more layers and (ii) a method for manufacturing the bonding pad.

### BACKGROUND OF THE INVENTION

The following will describe the structure of a conventional bonding pad with reference to FIGS. 6(a), 6(b), 7(a), and 7(b).

FIG. 6(a) is a cross-sectional view of a conventional bonding pad 110. FIG. 6(b) is a plan view illustrating the structure of an opening pathway P11 of the bonding pad 110.

The bonding pad 110 includes a base substrate 101, a first metal wiring layer 102, an interlayer insulation film 103, a second metal wiring layer 104, and a surface protective film 105. The base substrate 101 has an insulation film on the surface thereof. The first metal wiring layer 102 and the second metal wiring layer 104 are disposed via the interlayer insulation film 103. The surface protective film 105 has a bonding-use window W formed therein on the second metal wiring layer 104. The first metal wiring layer 102 and the second metal wiring layer 104 are electrically connected to each other via an opening pathway (opening)P11 formed in the interlayer insulation film 103. With the window W, bonding is performed by a method such as connection with a metal wire and form a metal pump.

In order to increase an area of a current pathway over which a current passes (hereinafter simply referred to as “current pathway”) between the first metal wiring layer 102 and the second metal wiring layer 104, the opening pathway P11 is formed so as to widely open on the first metal wiring layer 102, as illustrated in figures. However, such a structure have a height difference in the periphery of the window W, as illustrated in FIG. 6(a). The height difference occurs due to the opening pathway P11. This impairs the planarity of a pad surface to be subjected to bonding. Besides, in a multiplayer metal wiring structure with three or more layers, height differences are overlaid. This further impairs the planarity.

In order to solve the problem, a bonding pad 120 as illustrated in FIG. 7 has been suggested. FIG. 7(a) is a cross-sectional view of another conventional bonding pad 120. FIG. 7(b) is a plan view illustrating the structure of opening pathways P12 of the bonding pad 120. Note that FIG. 7(a) is a cross-sectional view taken along line C-c in FIG. 7(b).

The bonding pad 120 has the structure as illustrated in FIG. 7. That is, opening pathways formed in an interlayer insulation film 103 to connect between a first metal wiring layer 102 and a second metal wiring layer 104 are opening pathways P12 in the form of so-called via contact holes (or through-holes). The opening pathways P12 are filled with a contact plug material 106.

Such a structure reduces a height difference caused by an opening pathway and planarizes the surface of the interlayer insulation film 103, thus realizing an excellent planarity of the second metal wiring layer 104 formed on the interlayer insulation film 103, i.e. an excellent coplanarity of the pad surface. Generally, the opening pathway P12 is a micropore of which a diameter is smaller than a thickness of the second metal wiring layer 104. This allows the surface of the second metal wiring layer 104 to be nearly flat by filling the opening pathways P12 with the second metal wiring layer 104. The formation of a plurality of opening pathways P12 ensures a current pathway between the first metal wiring layer 102 and the second metal wiring layer 104.

Such a bonding pad is disclosed in Known Document 1 (Japanese Unexamined Patent publication No. 19248/1991 (Tokukaihei 3-19248; published on Jan. 28, 1991) through Known Document 4. Known Document 2 (Japanese Unexamined Patent publication No. 124844/1992 (Tokukaihei 4-124844; published on Apr. 24, 1992) discloses a bonding pad which has lath-shaped rectangular opening pathways. Known Document 3 (Japanese Unexamined Patent publication No. 243321/1993 (Tokukaihei 5-243321; published on Sep. 21, 1993) discloses in FIG. 1 a bonding pad applied to a four-layer metal structure. Known Document 4 (Japanese Unexamined Patent publication No. 161722/1995 (Tokukaihei 7-161722; published on Jun. 23, 1995) discloses in FIG. 1 a bonding pad applied to not only wire bonding but also wireless bonding using a bump metal, as a method of bonding to which the window W is subjected.

In a semiconductor integrated circuit, a power supply voltage V1 fed from a power supply line is reduced by a voltage drop V2 caused by a line that extends toward each circuit element. That is, a power supply voltage V3 actually fed to each circuit element is represented by V3=V1−V2. The power supply voltage V1 has increasingly become lower with miniaturization of semiconductor. integrated circuits. The voltage drop V2 defined by a product of a current I flowing a line and a resistance R of the line has increased. This is because a current I for driving a semiconductor integrated circuit tends to be constant or increase with the miniaturization of a semiconductor integrated circuit, and a wiring resistance R increases with the miniaturization of a semiconductor integrated circuit. That is, with the miniaturization of a semiconductor integrated circuit, the influence of the voltage drop V2 has become more serious.

In view of this, a power supply line of a semiconductor integrated circuit is not scaled down, in opposition to the miniaturization of the semiconductor integrated circuit. Especially in a high-speed logic LSI and an analogue circuit which requires to be operated with high accuracy, a width of the power supply line can be increased rather than decreased.

As described above, in the case of the power supply line, a resistance thereof is decreased with increase of a width of its metal wire. On the other hand, in the case of a via contact hole that contacts between metal wires, a resistance thereof is decreased with increase of a diameter of the via contact hole or increase of the number of via contact holes. However, these techniques have limitations due to the processing and layout restrictions, and may thus cause a significant voltage drop.

In view of such circumstances, the foregoing bonding pad 120 has a plurality of opening pathways P12. However, the bonding pad 120 has the problem that a current pathway of the bonding pad 120 is narrower than that of the bonding pad 110. This is because areas between the opening pathways P12 (areas P13 in FIG. 7(b)) do not function as current pathways.

Furthermore, the lath-shaped rectangular opening pathways disclosed in Known Document 2 give rise to a similar problem because areas between the opening pathways do not function as current pathways. These problems significantly affect especially a bonding pad for a power supply line. More specifically, since the bonding pad for a power supply line is a path over which all currents supplied to the semiconductor integrated circuit flow, an extremely high current is fed through the bonding pad. This causes a significant voltage drop, and may thus result in malfunction of the semiconductor integrated circuit.

In comparison with patterns including a linear pattern, a rectangular pattern, and a concave pattern, a pattern of via contact holes forming the opening pathways P12 in the bonding pad 120 is difficult to form by fine processes such as photolithography and etching in the manufacture process of a semiconductor integrated circuit, even if the patterns are identical in width of the via contact holes in a lateral direction. Thus, the bonding pad 120 has the problem that faulty electrical continuity may occur in the opening pathway P12. This problem impairs the miniaturization of the opening pathway P12.

### SUMMARY OF THE INVENTION

The present invention has been attained to solve the above problems. An object of the present invention is to provide: a bonding pad of a semiconductor integrated circuit which pad ensures the planarity of the surface of a metal wiring layer in an area corresponding to a window, i.e. the planarity of a pad surface, and allows for a sufficient current passage; and a method for manufacturing such a bonding pad. Another object of the present invention is to provide: a reliable bonding pad of a semiconductor integrated circuit which pad causes less faulty electrical continuity in opening pathways; and a method for manufacturing such a bonding pad. Still another object of the present invention is to provide: a semiconductor integrated circuit and an electronic device each of which includes the above bonding pad of a semiconductor integrated circuit and reduces their malfunctions.

In order to achieve the above objects, a bonding pad of the present invention of a semiconductor integrated circuit, includes: a multilayer metal wiring layer made up of at least two metal wiring layers; an interlayer insulation film being formed between the metal wiring layers; and a surface protective film, which is formed on a uppermost metal wiring layer of the multiplayer metal wiring layer, having a window for bonding, wherein a lower metal wiring layer and an upper layer metal wiring layer which is located immediately above the lower metal wiring layer are connected to each other via opening pathways that are formed in the interlayer insulation film between the metal wiring layers, the opening pathways having openings of at least two different widths including a first width and a second width, the first width being required to fill the opening pathway, the second width being larger than the first width, the openings being arranged lengthwise and crosswise.

According to the above arrangement, the bonding pad of the present invention of a semiconductor integrated circuit is arranged such that the opening pathways through which the metal wiring layers are connected have openings of at least two different widths including: a first width required to fill the opening pathway; and a second width being larger than the first width, and the openings are arranged lengthwise and crosswise. This makes it possible to increase an area of the opening pathways and to pass a larger amount of current.

With the arrangement in which the opening pathways have openings of the first width, the opening pathways are completely filled. By known polishing subsequently carried out, the planarity of the pad surface is ensured.

As described above, the present invention brings the effect of providing a bonding pad of a semiconductor integrated circuit which pad ensures the planarity of the surface of the metal wiring layer in an area corresponding to the window, i.e. the planarity of the pad surface, and enables a sufficient current passage.

In addition, with the arrangement in which the opening pathways have openings of the second width, the opening pathways are easily processed. This makes it possible to provide a reliable bonding pad of a semiconductor integrated circuit which pad causes less faulty electrical continuity in the opening pathways.

In order to achieve the above objects, a method for manufacturing a bonding pad of a semiconductor integrated circuit, according to the present invention, is a method for manufacturing a bonding pad including: a multilayer metal wiring layer made up of at least two metal wiring layers; an interlayer insulation film being formed between the metal wiring layers; and a surface protective film, which is formed on a uppermost metal wiring layer of the multiplayer metal wiring layer, having a window for bonding, wherein a lower metal wiring layer and an upper layer metal wiring layer which is located immediately above the lower metal wiring layer are connected to each other via opening pathways that are formed in the interlayer insulation film between the metal wiring layers, the method including the step of: forming, as the opening pathways, opening pathways having openings of at least two different widths including a first width and a second width, the first width being required to fill the opening pathway, the second width being larger than the first width, the openings being arranged lengthwise and crosswise.

According to the above arrangement, the manufacturing method of the present invention has the step of forming, as the opening pathways through which the metal wiring layers are connected, opening pathways having openings of at least two different widths including a first width required to fill the opening pathway and a second width being larger than the first width, the openings being arranged lengthwise and crosswise. With this arrangement, it is possible to provide a method for manufacturing a bonding pad of a semiconductor integrated circuit which Dad ensures the planarity of the surface of the metal wiring layer in an area corresponding to the window, i.e. the planarity of a pad surface; and allows for a sufficient current passage. Also, it is possible to provide a method for manufacturing a reliable bonding pad of a semiconductor integrated circuit which pad causes less faulty electrical continuity in the opening pathways.

In order to achieve the above objects, a semiconductor integrated circuit of the present invention includes the above bonding pad of a semiconductor integrated circuit. In order to achieve the above objects, an electronic device of the present invention includes the above semiconductor integrated circuit.

According to the above arrangement, the semiconductor integrated circuit of the present invention causes no bonding failures in the bonding pad and enables a sufficient current passage. This makes it possible to sufficiently ensure the capability of driving circuit elements in the semiconductor integrated circuit and therefore reduce the malfunction of the semiconductor integrated circuit. Accordingly, it is possible to reduce the malfunction of an electronic device of the present invention including the above semiconductor integrated circuit. As described above, it is possible to provide a semiconductor integrated circuit and an electronic device each of which includes the bonding pad of the present invention of a semiconductor integrated circuit and reduces their malfunction. Especially, if the bonding pad of the present invention is used as a bonding pad for a power source line, the aforementioned effects become more significant.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1(a) is a cross-sectional view of a bonding pad of the present embodiment of a semiconductor integrated circuit.

FIG. 1(b) is a cross-sectional view of a bonding pad of the present embodiment of a semiconductor integrated circuit.

FIG. 1(c) is a plan view illustrating a pattern of opening pathways in the bonding pad.

FIG. 2(a) is a view illustrating a step for manufacturing the bonding pad, by using the cross section illustrated in FIG. 1(a).

FIG. 2(b) is a view illustrating a step for manufacturing the bonding pad, by using the cross section illustrated in FIG. 1(a).

FIG. 2(c) is a view illustrating a step for manufacturing the bonding pad, by using the cross section illustrated in FIG. 1(a).

FIG. 2(d) is a view illustrating a step for manufacturing the bonding pad, by using the cross section illustrated in FIG. 1(a).

FIG. 2(e) is a view illustrating a step for manufacturing the bonding pad, by using the cross section illustrated in FIG. 1(a).

FIG. 2(f) is a view illustrating a step for manufacturing the bonding pad, by using the cross section illustrated in FIG. 1(a).

FIG. 3(a) is a view illustrating a step for manufacturing the bonding pad, by using the cross section illustrated in FIG. 1(b).

FIG. 3(b) is a view illustrating a step for manufacturing the bonding pad, by using the cross section illustrated in FIG. 1(b).

FIG. 3(c) is a view illustrating a step for manufacturing the bonding pad, by using the cross section illustrated in FIG. 1(b).

FIG. 3(d) is a view illustrating a step for manufacturing the bonding pad, by using the cross section illustrated in FIG. 1(b).

FIG. 3(e) is a view illustrating a step for manufacturing the bonding pad, by using the cross section illustrated in FIG. 1(b).

FIG. 3(f) is a view illustrating a step for manufacturing the bonding pad, by using the cross section illustrated in FIG. 1(b):

FIG. 4(a) is a view illustrating another pattern of opening pathways in the bonding pad.

FIG. 4(b) is a view illustrating still another pattern of opening pathways in the bonding pad.

FIG. 4(c) is a view illustrating yet another pattern of opening pathways in the bonding pad.

FIG. 4(d) is a view illustrating further another pattern of opening pathways in the bonding pad.

FIG. 5(a) is a view illustrating another pattern of opening pathways in the bonding pad.

FIG. 5(b) is a view illustrating still another pattern of opening pathways in the bonding pad.

FIG. 5(c) is a view illustrating yet another pattern of opening pathways in the bonding pad.

FIG. 6(a) is a cross-sectional view of a bonding pad of the conventional semiconductor integrated circuit.

FIG. 6(b) is a plan view illustrating an opening pathway of the bonding pad illustrated in FIG. 6(a).

FIG. 7(a) is a cross-sectional view of a bonding pad of the conventional semiconductor integrated circuit.

FIG. 7(b) is a plan view illustrating an opening pathway of the bonding pad illustrated in FIG. 7(a).

### DESCRIPTION OF THE EMBODIMENTS

The following will describe an embodiment of the present invention with reference to drawings.

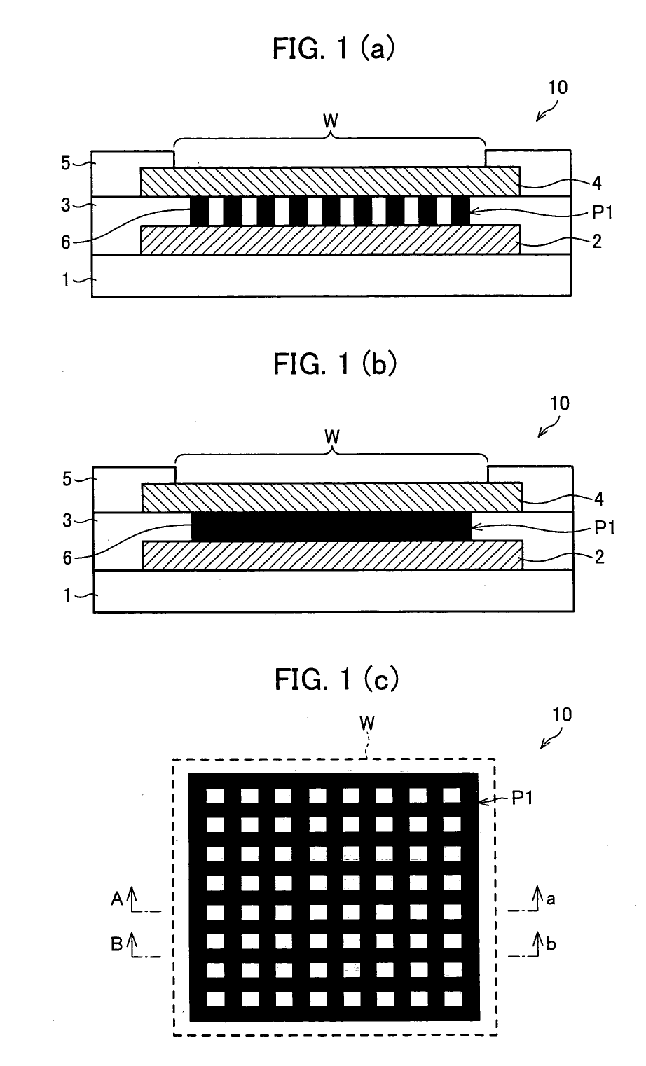

FIGS. 1(a) and 1(b) are cross-sectional views of a bonding pad 10 of a semiconductor integrated circuit according to the present embodiment. FIG. 1(c) is a plan view illustrating the opening pathways P1 of the bonding pad 10. Note that FIG. 1(a) is a cross-sectional view taken along line A-a in FIG. 1(c), and FIG. 1(b) is a cross-sectional view taken along line B-b in FIG. 1(c).

As illustrated in FIGS. 1(a) and 1(b), the bonding pad 10 includes a base substrate 1, a first metal wiring layer 2, an interlayer insulation film 3, a second metal wiring layer 4, and a surface protective film 5, which are stacked in layers in this order. The first metal wiring layer 2 and the second metal wiring layer 4 are electrically connected to each other through a contact plug material 6 in opening pathways (openings) P1 formed in the interlayer insulation film 3. The surface protective film 5 is provided with a bonding-use window W, through which bonding is carried out by a method such as connection with a metal wire or formation of a metal bump.

In the bonding pad 10, the opening pathways P1 have two types of openings of different widths, which openings are arranged lengthwise and crosswise. More specifically, the opening pathways P1 includes: a first pathway having an opening of a width required to fill the opening pathway P1; and a second pathway having an opening of a width sufficiently larger than a width of the opening of the first pathway. These openings are arranged lengthwise and crosswise, which forms a “mesh grid pattern” as illustrated in FIG. 1(c).

With this arrangement, the bonding pad 10 is allowed to have a larger opening pathway area, in comparison with the conventional bonding pad 120, in which a plurality of opening pathways like the opening pathways P12 exist separately. This allows the bonding pad 10 to have a sufficient current passage. With the arrangement in which the opening pathways have openings of a width required to fill the opening pathway P1, the opening pathways are completely filled. By a known polishing subsequently carried out, the planarity of the pad surface is ensured. Further, with the arrangement in which the opening pathways P1 have openings of the second width, which is larger than that of the conventional opening pathway P12, the opening pathways P1 are easily processed. Thus, it is possible to realize a reliable bonding pad that causes less faulty electrical continuity in opening pathways.

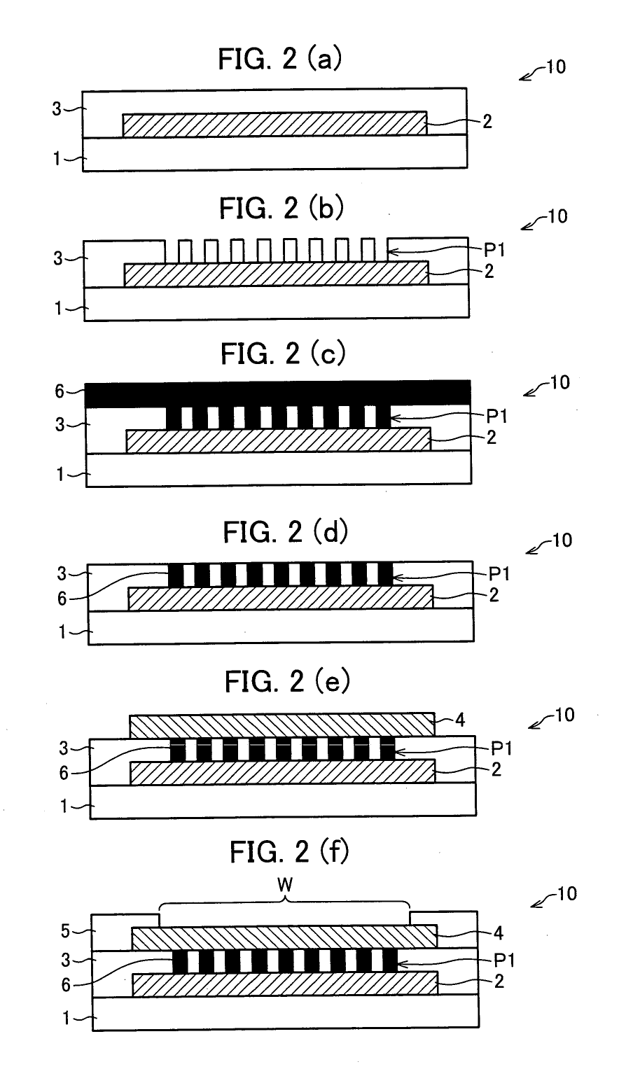

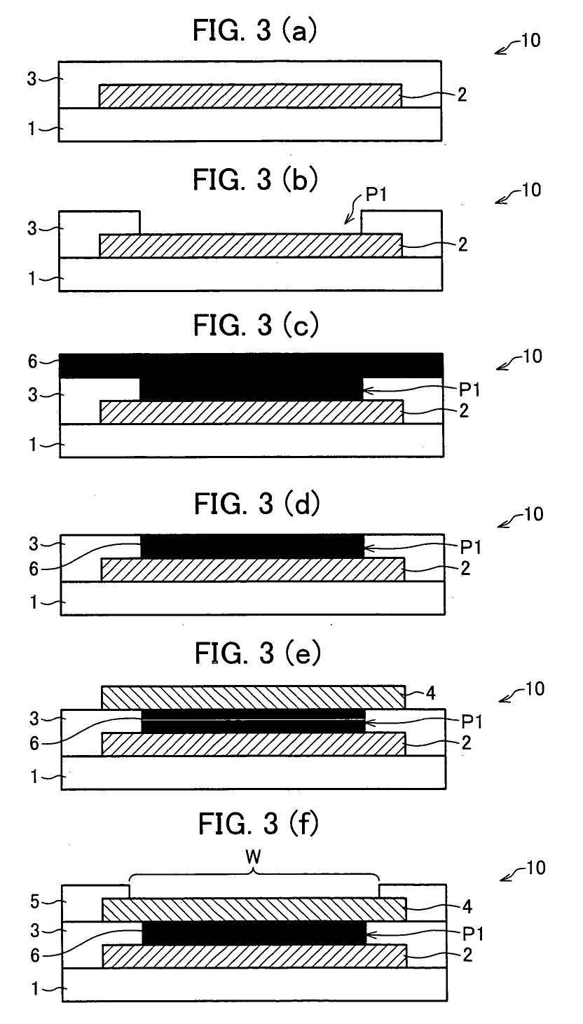

Next, the following will describe a method for manufacturing such a bonding pad 10. FIGS. 2(a) through 2(f) and FIGS. 3(a) through 3(f) illustrate steps for manufacturing the bonding pad 10. FIGS. 2(a) through 2(f) are cross-sectional views taken along the line A-a shown in FIG. 1(a). FIGS. 3(a) through 3(f) are cross-sectional views taken along the line B-b shown in FIG. 1(b). In FIGS. 2(a) through 2(f) and FIGS. 3(a) through 3(f) and the following descriptions, commonly conducted steps are omitted, including the step of applying a photoresist, exposure to light, and development, the step of removing a photoresist after etching, and the step of washing after etching and photoresist removal.

First of all, as illustrated in FIG. 2(a) and FIG. 3(a), a first metal wiring layer 2 is deposited by sputtering on a base substrate having a semiconductor integrated circuit (not shown) formed thereon appropriately by a known method. The first metal wiring layer 2 is processed in a predetermined pattern by known methods of photolithography and etching. Then, an interlayer insulation film 3 is deposited on the first metal wiring layer 2 by a known method such as CVD (Chemical Vapor Deposition).

It is preferable that an insulation film is formed on the upper surface (surface) of the base substrate 1. The insulation film can be a silicone oxide film, a silicon nitride film, or other insulating dielectric film. The first metal wiring layer 2 is generally made of aluminum or alloy containing aluminum. However, the first metal wiring layer 2 may be made of copper, titanium, tungsten, or other high melting point metal. Alternatively, the first metal wiring layer 2 may have a laminated structure with (a) aluminum or alloy containing aluminum and (b) copper, titanium, tungsten, or other high melting point metal. The interlayer insulation film 3 can be a silicone oxide film, a silicon nitride film, or other insulating dielectric film. In order to ensure the planarity of the pad surface, the interlayer insulation film 3 may be planarized by a known CMP (Chemical Mechanical Polishing).

Then, as illustrated in FIGS. 2(b) and 3(b), opening pathways P1 are formed in the interlayer insulation film 3. More specifically, opening pathways shaped like grooves are formed in a “mesh grid pattern” as illustrated in FIG. 1(c) by known methods of photolithography and etching. Also, the opening pathways are formed in the interlayer insulation film 3 at such a depth that the opening pathways reach the surface of the first metal wiring layer 2. In this step, an opening formed in a direction along the line A-a is formed so as to have the first width, whereas an opening in a direction along the line B-b is formed so as to have the second width.

Note that the width required to fill the opening pathway P1 is preferably the same as a diameter of a via contact hole in the semiconductor integrated circuit formed on the base substrate 1 or a minimum size of a wiring gutter formed by a known damascene process. In order to facilitate the manufacture in consideration of the subsequent step of filling the opening pathways, the width required to fill the opening pathway P1 is preferably not more than a diameter of a via contact hole in the semiconductor integrated circuit formed on the base substrate 1 or a maximum size of a wiring gutter formed by a known damascene process. The width of the interlayer insulation film 3 that exists between the opening pathway P1 and its adjacent opening pathway P1 is preferably the same as a minimum distance between via contact holes formed in one chip or a minimum distance between the opening pathways P1 formed by a known damascene process.

Thereafter, as illustrated in FIGS. 2(c) and 3(c), the opening pathways P1 formed in the interlayer insulation film 3 are filled with a contact plug material 6 by a known technique. In this step, the contact plug material 6 is deposited thick enough to fill the opening pathways P1 with, so that filling the opening pathways P1 are properly carried out. This allows the surface of the interlayer insulation film 3 to be nearly flat. For the improvement in planarity, a thickness of a film of the contact plug material 6 is preferably larger than the width of the opening formed in the direction along the line A-a. When the opening formed in the direction along the line A-a is filled with the contact plug material 6 before the opening formed in the direction along the line B-b is filled with the contact plug material 6, a height of the surface of the contact plug material 6 in the opening formed in the direction along the line B-b becomes the same as a height of the surface of the contact plug material 6 in the opening formed in the direction along the line A-a. The contact plug material 6 is made of tungsten, aluminum or copper.

Then, as illustrated in FIGS. 2(d) and 3(d), an unwanted contact plug material 6 formed on the interlayer insulation film 3 is removed by a known etch back process, a known CMP, or other method. This step makes the surface of the interlayer insulation film 3 become flattened.

Thereafter, as illustrated in FIGS. 2(e) and 3(e), a second metal wiring layer 4 is deposited on the interlayer insulation film 3 by sputtering. The second metal wiring layer 4 is processed into a predetermined pattern by known methods of photolithography and etching. The second metal wiring layer 4 is generally made of aluminum or alloy containing aluminum. However, the second metal wiring layer 4 may be made of copper, titanium, tungsten, or other high melting point metal. Alternatively, the second metal wiring layer 4 may have a laminated structure with (a) aluminum or alloy containing aluminum and (b) copper, titanium, tungsten, or other high melting point metal.

Then, as illustrated in FIGS. 2(f) and 3(f), a surface protective film 5 is deposited on the second metal wiring layer 4 by CVD. The surface protective film 5, which is a diffusion protective film that prevents the entry of water, ions, and others from outside, is a PSG (phophos silicate glass) film, a silicone nitride film, a silicon oxide nitride film, or the like film. Then, a window W is formed in the surface protective film 5 by known methods of photolithography and etching at such a depth that the window W reaches the surface of the second metal wiring layer 4. In the present embodiment, the window W is formed so as to reach the surface of the second metal wiring layer 4. However, the window W may be formed as in Known Document 1, i.e. the window W may be formed so as to reach the surface of the interlayer insulation film 3.

In the present embodiment, the opening pathways P1 are filled with the contact plug material 6. However, the opening pathways P1 may be filled directly with a material of the second metal wiring layer 4, instead of the contact plug material 6. In this case, in order to reduce the height difference caused by the opening pathways P1, the width of the opening formed in the direction along the line A-a is preferably smaller than the thickness of the second metal wiring layer 4.

The above descriptions involve the bonding pad 10 having the opening pathways P1 forming a “mesh grid pattern” in plan view. However, the arrangement (two-dimensional pattern) of the opening pathways is not limited to this. The following will describe other arrangements of opening pathways.

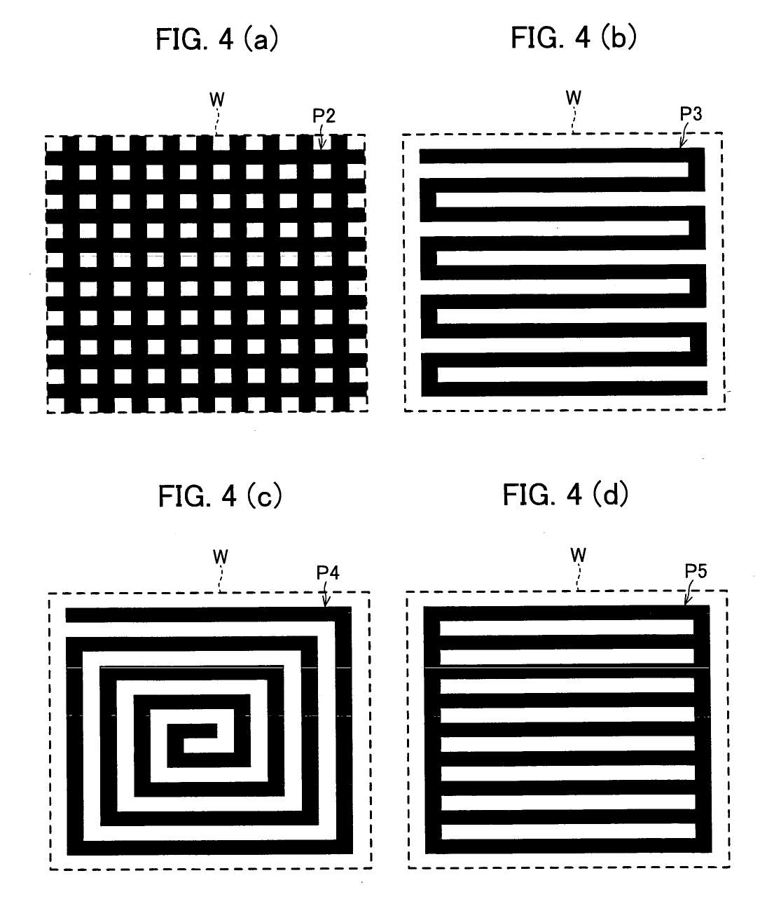

FIGS. 4(a) through 4(d) illustrate other arrangements of opening pathways. FIG. 4(a) illustrates opening pathways P2 arranged in a “crisscross pattern”. FIG. 4(b) illustrates opening pathways P3 arranged in a “folded pattern”. FIG. 4(c) illustrates opening pathways P4 arranged in a “spiral pattern”. FIG. 4(d) illustrates opening pathways P5 arranged in a “striped pattern”. The bonding pad of the present invention which pad has the opening pathways in the above-mentioned patterns can be easily formed by a method similar to the foregoing manufacturing method.

Like the opening pathways P1 arranged in a “mesh grid pattern”, the opening pathways arranged as in FIGS. 4(a) through 4(d), i.e. the opening pathways P2 arranged in a “crisscross pattern”, the opening pathways P3 arranged in a “folded pattern”, the opening pathways P4 arranged in a “spiral pattern”, and the opening pathways P5 arranged in a “striped pattern” each realize a reliable bonding pad which enables a sufficient current passage and less faulty electrical continuity in opening pathways, while ensuring the planarity of the pad surface. In particular, for example, with the opening pathways P2 arranged in a “crisscross pattern”, it is possible to provide a bonding pad capable of passing a larger amount of current as well as having the above effects, in comparison with the opening pathways arranged in the other patterns. Furthermore, the opening pathways P3 arranged in a “folded pattern”, the opening pathways P4 arranged in a “spiral pattern”, the opening pathways P5 arranged in a “striped pattern”, have more openings at the second width than the opening pathways P1 and pathways P2, and are therefore more easily processed. This makes it possible to provide a more reliable bonding pad that causes much less faulty electrical continuity.

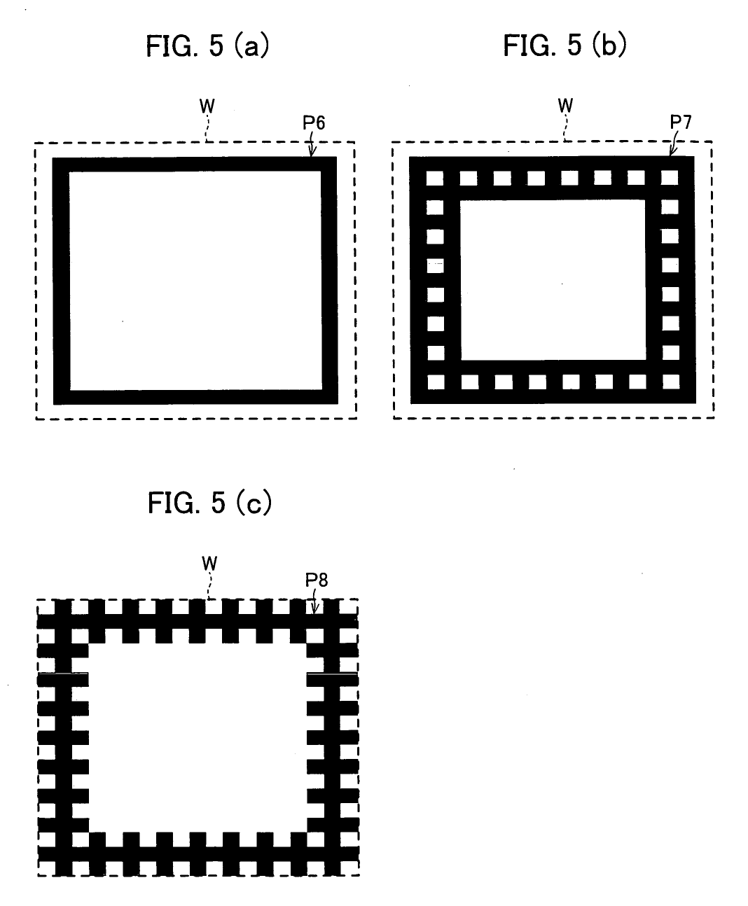

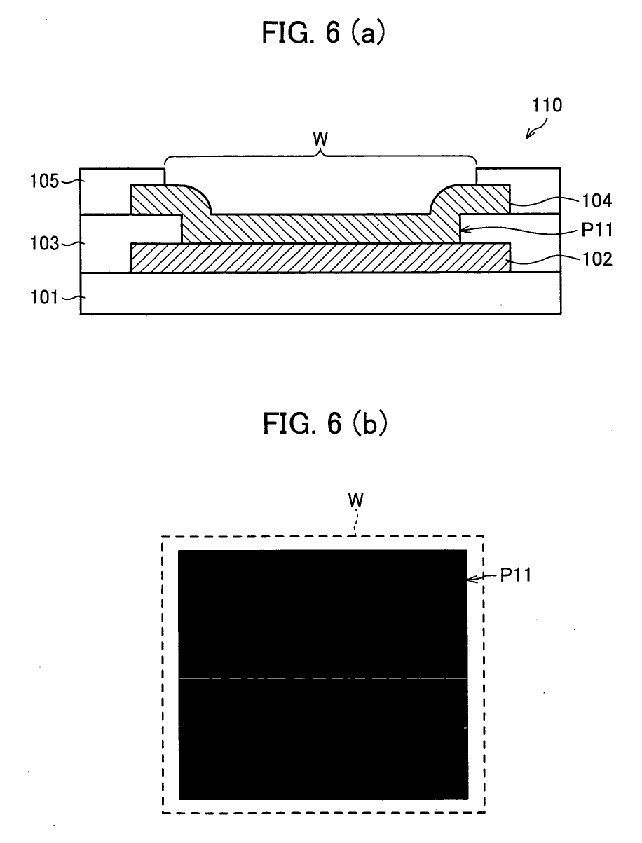

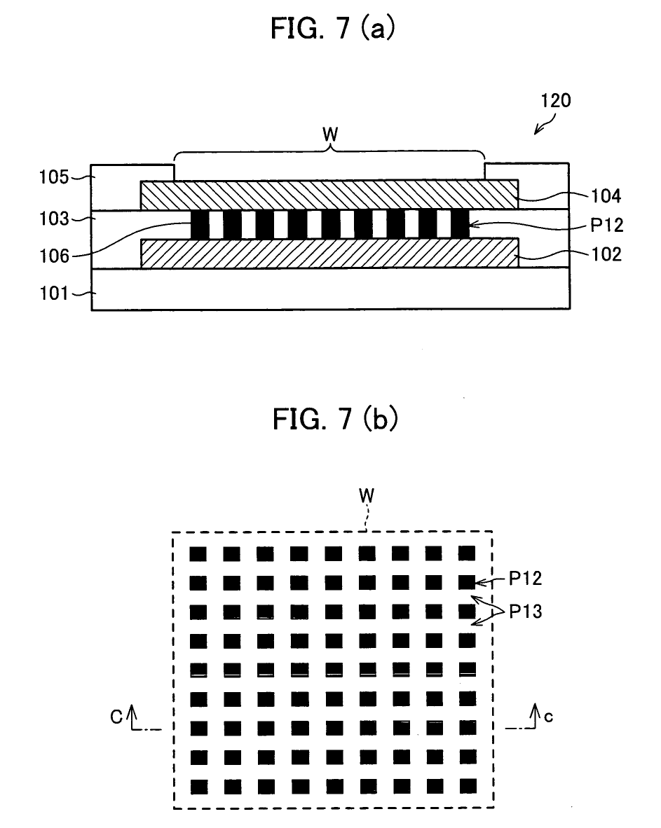

If a sufficient amount of current is ensured with respect to the operation of the semiconductor integrated circuit, opening pathways may be arranged in patterns as illustrated in FIGS. 5(a) through 5(c). FIGS. 5(a) through 5(c) illustrate still another arrangements of opening pathways.

In the manufacture process of the semiconductor integrated circuit, a plurality of semiconductor integrated circuit chips each containing a bonding pad are formed on one wafer, and then directly subjected to a wafer test. In the wafer test, physical impact is given to the center of the bonding pad due to tester probing. In a case where via contact holes are formed as the opening pathways, the above impact may cause damage to the opening pathways and therefore give rise to the problem such as faulty electrical continuity. In view of this, it is preferable that the opening pathways are not formed in an area of the interlayer insulation film corresponding to the center of the bonding pad and its vicinity.

In view of the above problem, the inventors has contrived the opening pathways P6 through P8 illustrated in FIGS. 5(a) through 5(c), in which the opening pathways are not formed in an area of the interlayer insulation film 3 corresponding to the center of the window W and its vicinity. For example, as illustrated in FIG. 5(a), the opening pathways P6 are arranged such that the opening pathways are formed only in an area of the interlayer insulation film 3 corresponding to an area around the window W. The opening pathways P7 illustrated in FIG. 5(b) and the opening pathways P8 illustrated in FIG. 5(c) are arranged as with the opening pathways P1 illustrated in FIG. 1(c) and the opening pathways P2 illustrated in FIG. 4(a), respectively, except that the opening pathways are not formed in an area of the interlayer insulation film 3 corresponding to the center of the window W and its vicinity. Such arrangements of the opening pathways prevent the opening pathways from being given physical impact caused in the course of the wafer test, and prevents the occurrence of faulty electrical continuity caused by the damage to the opening pathways. It is needless to say that the opening pathways P6 through P8 realize sufficient current passage while ensuring the planarity of the pad surface and also realize a reliable bonding pad which has less faulty electrical continuity in the opening pathways.

In the above-described present embodiment, the opening pathways are provided in an area of the interlayer insulation film corresponding to the area of the window W. However, the present embodiment is not limited to this arrangement. Alternatively, the opening pathways may be provided in an area of the interlayer insulation film corresponding to the periphery of the window W, for example. Further, for simple explanation of the concept of the present invention, the multiplayer metal wiring layer included in the bonding pad is the layer made up of two metal wiring layers in the present embodiment. However, the present embodiment is not limited to this arrangement. Alternatively, the multiplayer metal wiring layer may be a layer made up of three or more metal wiring layers. In this case, an interlayer insulation film, opening pathways in the interlayer insulation film, and a metal wiring layer are added as appropriate. The multiplayer metal wiring layer made up of three or more metal wiring layers does not impair the foregoing advantageous effects of the present invention concerning the relationship between a lower metal wiring layer and an upper metal wiring layer which is immediately above the lower metal wiring layer.

The present invention is not limited to the aforementioned embodiment and is susceptible of various changes within the scope of the accompanying claims. In addition, a semiconductor integrated circuit including a bonding pad of the present invention and an electronic device including the semiconductor integrated circuit are included within the technical scope of the present invention. The semiconductor integrated circuit is a typical semiconductor integrated circuit. With the bonding pad of the present invention, the semiconductor integrated circuit causes no bonding failures in the bonding pad and enables sufficient current passage. This makes it possible to sufficiently ensure the capability of driving circuit elements and therefore reduce the malfunction of the semiconductor integrated circuit. Accordingly, it is possible to reduce the malfunction of the electronic device. Especially, if the bonding pad of the present invention is used as a bonding pad for a power source line, the aforementioned effects become more significant.

The bonding pad of the present embodiment of a semiconductor integrated circuit may be arranged such that the second opening width may be as large as possible.

According to the above arrangement, the second opening width is as large as possible, which allows the opening pathways to be more easily processed. This makes it possible to provide a more reliable bonding pad with much less faulty electrical continuity in the semiconductor integrated circuit.

Generally, the opening pathways are filled with the contact plug material. However, the present embodiment is not limited to this. Alternatively, the opening pathways may be filled directly with an upper metal wiring layer of metal wiring layers that are connected through the opening pathways.

In view of this, the bonding pad of the preset embodiment of a semiconductor integrated circuit may be arranged such that the first opening width is smaller than a thickness of the upper metal wiring layer.

According to the above arrangement the first opening width is smaller than a thickness of the upper metal wiring layer. This makes it possible to reduce a height difference caused by opening pathways and ensure the planarity of the pad surface even when the opening pathways are filled directly with the upper metal wiring layer.

The bonding pad of the preset embodiment of a semiconductor integrated circuit may be arranged such that the opening pathways forms any one of a spiral pattern, a folded pattern, a striped pattern, a mesh grid pattern, and a crisscross pattern in plan view.

According to the above arrangement, the opening pathways form any one of a spiral pattern, a folded pattern, a striped pattern, a mesh grid pattern, and a crisscross pattern in plan view. This makes it possible to provide a bonding pad of a semiconductor integrated circuit which pad ensures the planarity of the surface of a metal wiring layer in an area corresponding to the window, i.e. the planarity of the pad surface, and allows for a sufficient current passage. Moreover, it is possible to provide a reliable bonding pad that causes less faulty electrical continuity in the opening pathways. In particular, for example, with the opening pathways arranged in a “crisscross pattern”, it is possible to provide a bonding pad capable of passing a larger amount of current as well as having the above effects, in comparison with the opening pathways arranged in the other patterns. Furthermore, the opening pathways arranged in a “folded pattern”, the opening pathways arranged in a “spiral pattern”, the opening pathways arranged in a “striped pattern”, have more openings at the second width than the other opening pathways, and are therefore more easily processed. This makes it possible to provide a more reliable bonding pad that causes much less faulty electrical continuity.

In the manufacture process of the semiconductor integrated circuit, a plurality of semiconductor integrated circuit chips each containing a bonding pad are formed on one wafer, and then directly subjected to a wafer test. In the wafer test, physical impact is given to the center of the bonding pad due to tester probing. In a case where via contact holes are formed as the opening pathways, the above impact may cause damage to the opening pathways and therefore give rise to the problem such as faulty electrical continuity. In view of this, it is preferable that the opening pathways are not formed in an area of the interlayer insulation film corresponding to the center of the bonding pad and its vicinity.

In view of this, a bonding pad of the present embodiment of a semiconductor integrated circuit may be arranged such that the opening pathways are not formed in an area of the interlayer insulation film corresponding to the center of the window and its vicinity.

According to the above arrangement, the opening pathways are not formed in an area of the interlayer insulation film corresponding to the center of the window and its vicinity. This makes it possible to prevent the opening pathways from being given physical impact caused in the course of the wafer test, and prevents the occurrence of faulty electrical continuity caused by the damage to the opening pathways.

The bonding pad of the preset embodiment of a semiconductor integrated circuit may be arranged such that the first opening width is not more than a maximum width of the opening pathway between metal wiring layers in the semiconductor integrated circuit.

According to the above arrangement, an opening width required to fill the opening pathway is not more than a maximum width of the opening pathway between the metal wiring layers in the semiconductor integrated circuit. With this arrangement, the semiconductor integrated circuit is easily manufactured.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A bonding pad of a semiconductor integrated circuit, comprising: a multilayer metal wiring layer made up of at least two metal wiring layers; an interlayer insulation film being formed between the metal wiring layers; and a surface protective film, which is formed on a uppermost metal wiring layer of the multiplayer metal wiring layer, having a window for bonding, wherein a lower metal wiring layer and an upper layer metal wiring layer which is located immediately above the lower metal wiring layer are connected to each other via opening pathways that are formed in the interlayer insulation film between the metal wiring layers,
the opening pathways having openings of at least two different widths including a first width and a second width, the first width being required to fill the opening pathway, the second width being larger than the first width, the openings being arranged lengthwise and crosswise.

2. The bonding pad according to claim 1, wherein:
the second width is as large as possible.

3. The bonding pad according to claim 1, wherein:
the first width is smaller than a thickness of the upper metal wiring layer.

4. The bonding pad according to claim 1, wherein:
the opening pathways form any one of a spiral pattern, a folded pattern, a striped pattern, a mesh grid pattern, and a crisscross pattern in plan view.

5. The bonding pad according to claim 1, wherein:
the opening pathways are not formed in an area of the interlayer insulation film corresponding to a center of the window and its vicinity.

6. The bonding pad according to claim 1, wherein:
the first width is not more than a maximum width of the opening pathway between the metal wiring layers in the semiconductor integrated circuit.

7. A method for manufacturing a bonding pad of a semiconductor integrated circuit, the bonding pad comprising: a multilayer metal wiring layer made up of at least two metal wiring layers; an interlayer insulation film being formed between the metal wiring layers; and a surface protective film, which is formed on a uppermost metal wiring layer of the multiplayer metal wiring layer, having a window for bonding, wherein a lower metal wiring layer and an upper layer metal wiring layer which is located immediately above the lower metal wiring layer are connected to each other via opening pathways that are formed in the interlayer insulation film between the metal wiring layers,
the method comprising the step of:
forming, as the opening pathways, opening pathways having openings of at least two different widths including a first width and a second width, the first width being required to fill the opening pathway, the second width being larger than the first width, the openings being arranged lengthwise and crosswise

8. A semiconductor integrated circuit including a bonding pad comprising: a multilayer metal wiring layer made up of at least two metal wiring layers; an interlayer insulation film being formed between the metal wiring layers; and a surface protective film, which is formed on a uppermost metal wiring layer of the multiplayer metal wiring layer, having a window for bonding, wherein a lower metal wiring layer and an upper layer metal wiring layer which is located immediately above the lower metal wiring layer are connected to each other via opening pathways that are formed in the interlayer insulation film between the metal wiring layers,
the opening pathways having openings of at least two different widths including a first width and a second width, the first width being required to fill the opening pathway, the second width being larger than the first width, the openings being arranged lengthwise and crosswise.

9. An electronic device including a semiconductor integrated circuit which includes a bonding pad comprising: a multilayer metal wiring layer made up of at least two metal wiring layers; an interlayer insulation film being formed between the metal wiring layers; and a surface protective film, which is formed on a uppermost metal wiring layer of the multiplayer metal wiring layer, having a window for bonding, wherein a lower metal wiring layer and an upper layer metal wiring layer which is located immediately above the lower metal wiring layer are connected to each other via opening pathways that are formed in the interlayer insulation film between the metal wiring layers,
the opening pathways having openings of at least two different widths including a first width and a second width, the first width being required to fill the opening pathway, the second width being larger than the first width, the openings being arranged lengthwise and crosswise.
